(19) United States
(12) Patent Application Publication
(10) Pub. No.: US 2025/0183157 A1
(43) Pub. Date: Jun. 5, 2025

(54) DUAL-VIA DEVICE, LAYOUT, AND METHOD

(71) Applicant: TAIWAN SEMICONDUCTOR MANUFACTURING COMPANY, LTD., Hsinchu (TW)

(72) Inventors: Jia-Hong GAO, Hsinchu (TW); Chih-Liang CHEN, Hsinchu (TW); Hui-Zhong ZHUANG, Hsinchu (TW); Guo-Huei WU, Hsinchu (TW)

(21) Appl. No.: 18/524,720

(22) Filed: Nov. 30, 2023

(51) Int. Cl. H01L 23/522; H01L 21/8238; H01L 23/48; H01L 23/528; H01L 27/092; H01L 29/06; H01L 29/423; H01L 29/66; H01L 29/775; H01L 29/786

(52) U.S. Cl. CPC H01L 23/5226; H01L 23/481; H01L 23/5283; H10D 30/014; H10D 30/43; H10D 30/6735; H10D 30/6757; H10D 62/121; H10D 84/0167; H10D 84/0186; H10D 84/038; H10D 84/85

(57) ABSTRACT

An integrated circuit (IC) device includes a first transistor positioned on a front side of a semiconductor substrate, the first transistor including a first gate electrode, first and second epitaxial regions, a first channel extending between the first and second epitaxial regions and through the first gate electrode, and first and second metal-like defined (MD) segments directly overlying the respective first and second epitaxial regions. A first power rail is positioned on a back side of the semiconductor substrate, a first via structure extends from the first epitaxial region to the first power rail, and a second via structure extends from the first MD segment to the first power rail.

### BACKGROUND

The ongoing trend in miniaturizing integrated circuits (ICs) has resulted in progressively smaller devices which consume less power, yet provide more functionality at higher speeds than earlier technologies. Such miniaturization has been achieved through design and manufacturing innovations tied to increasingly strict specifications. Various electronic design automation (EDA) tools are used to generate, revise, and verify designs for semiconductor devices while ensuring that IC structure design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are respective plan and cross-sectional views of an IC layout and corresponding IC device, in accordance with some embodiments.

FIGS. 2A-2C are plan and cross-sectional views of an IC layout and corresponding IC device, in accordance with some embodiments.

FIG. 3 is a plan view of an IC layout and corresponding IC device, in accordance with some embodiments.

FIG. 4 is a plan view of an IC layout and corresponding IC device, in accordance with some embodiments.

FIGS. 5A and 5B are plan views of IC layouts and corresponding IC devices, in accordance with some embodiments.

FIG. 6 is a plan view of an IC layout and corresponding IC device, in accordance with some embodiments.

FIG. 7 is a flowchart of a method of manufacturing an IC device, in accordance with some embodiments.

FIG. 8 is a flowchart of a method of generating an IC layout diagram, in accordance with some embodiments.

FIG. 9 is a block diagram of an IC layout diagram generation system, in accordance with some embodiments.

FIG. 10 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, steps, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, an IC device and manufacturing method based on an IC layout diagram include a structure, e.g., a transistor, on a front side of a semiconductor substrate, the structure including a gate electrode, first and second epitaxial regions, a channel extending between the first and second epitaxial regions and through the gate electrode, and first and second metal-like defined (MD) segments directly overlying the first and second epitaxial regions. A power rail is positioned on a back side of the semiconductor substrate, a first via structure, e.g., a back-side via, extends from the first epitaxial region to the power rail, and a second via structure, e.g., a feed-through via (FTV), extends from the first MD segment to the power rail.

An electrical path from the power rail to the first MD segment thereby includes a parallel arrangement of the two via structures whereby the dual-via path resistance is reduced compared to approaches in which electrical paths from power rails to front-side structures do not include parallel arrangements of via structures. The reduced path resistance acts to reduce parasitic voltage drops due to current flow, i.e., IR voltage drops, compared to such other approaches.

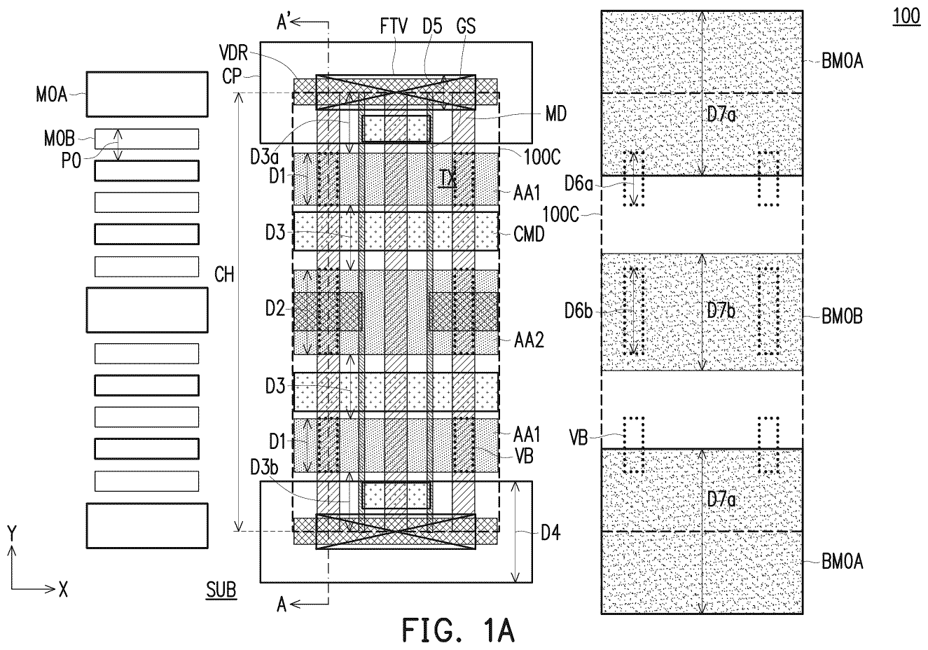

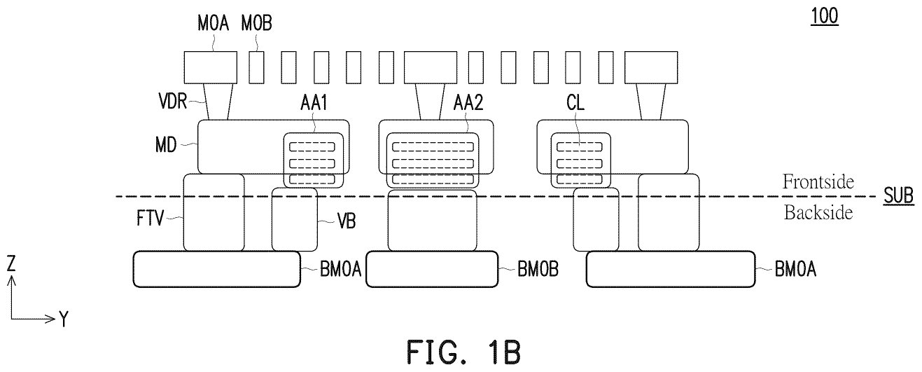

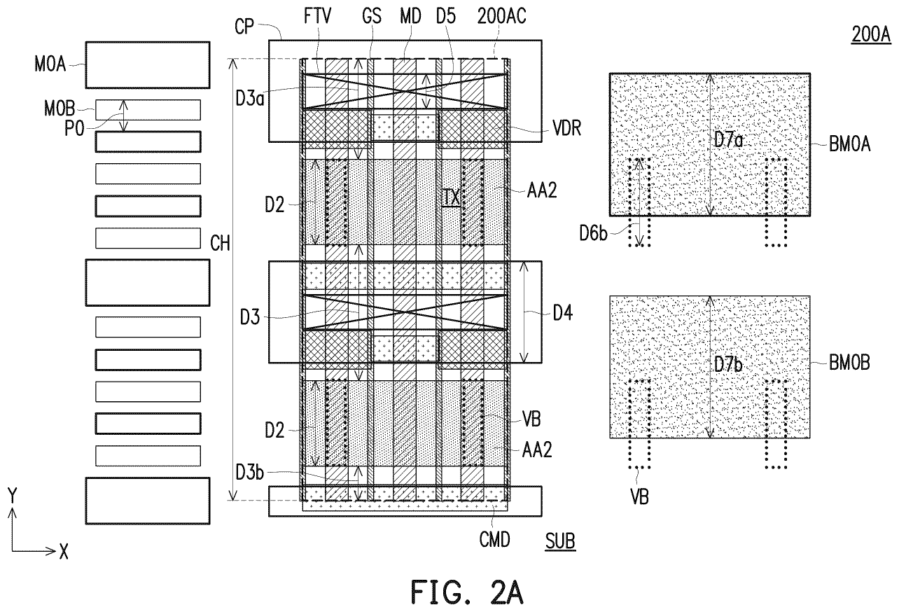

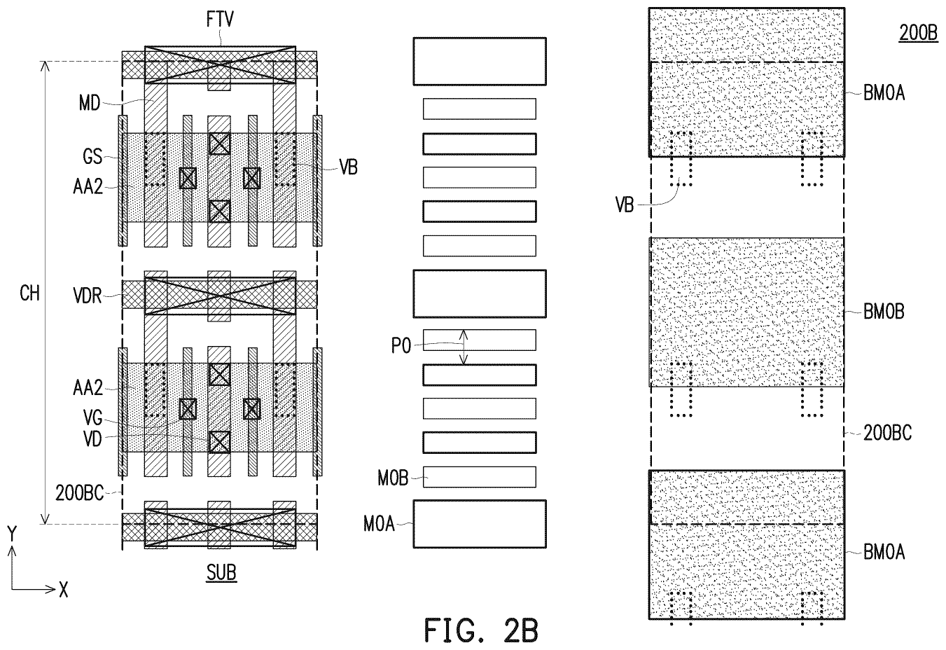

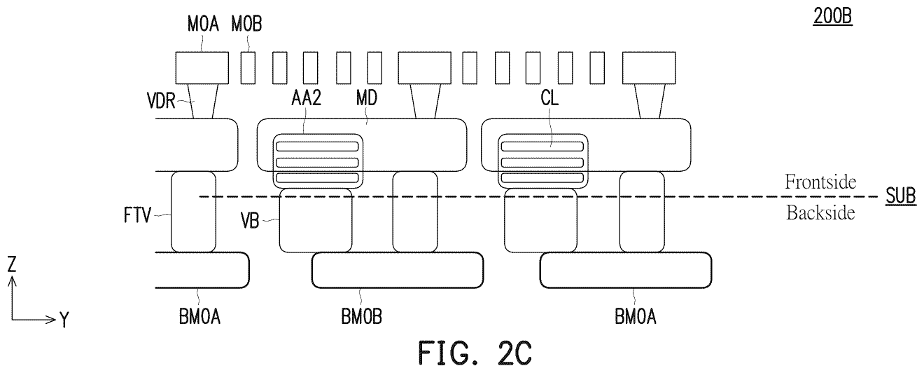

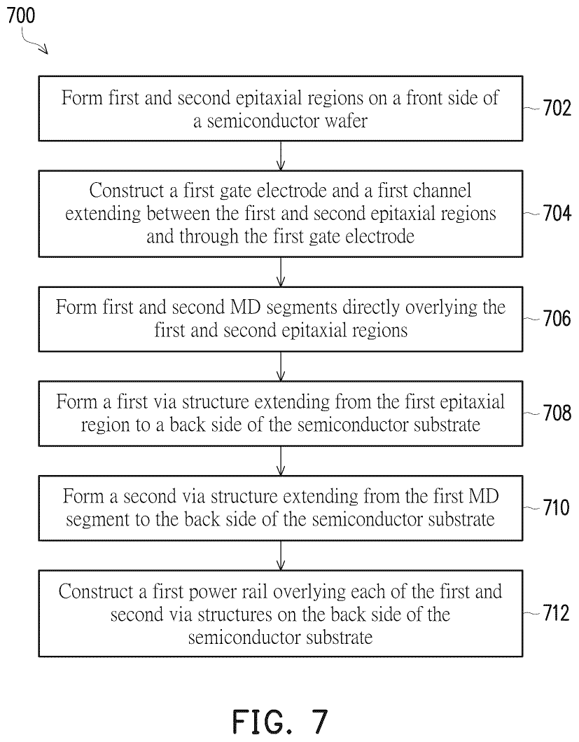

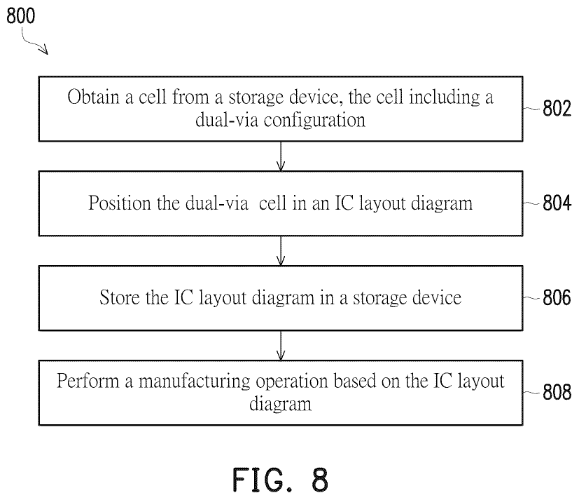

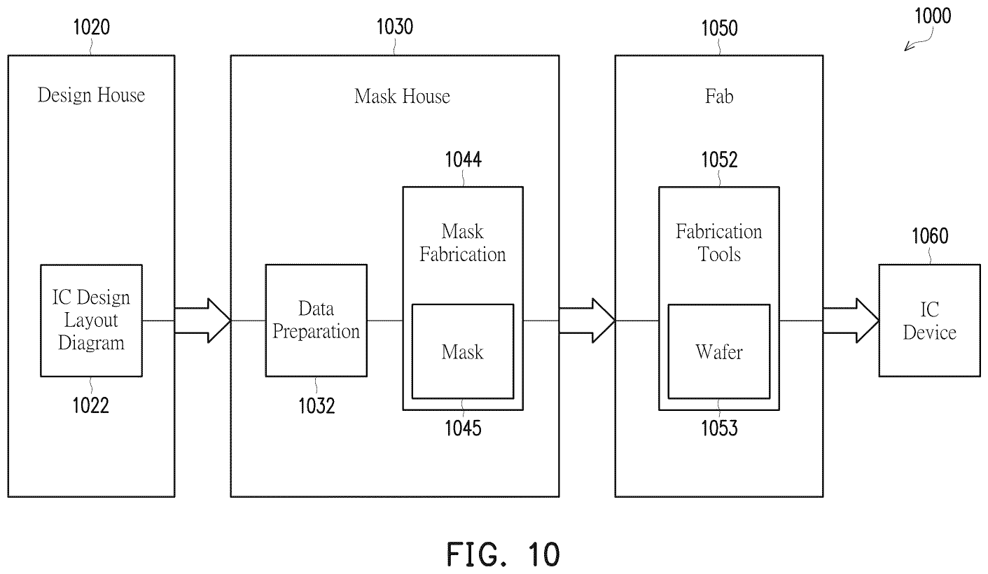

As discussed below, FIGS. 1A, 2A, 2B, and 3-6 depict plan views and FIGS. 1B and 2C depict cross-sectional views, in some embodiments. Each of FIGS. 1A-6 is a device/layout diagram in which the reference designators represent both IC device features and the IC layout features used to at least partially define the corresponding IC device features in a manufacturing process, e.g., a method 700 discussed below with respect to FIG. 7 and/or an IC manufacturing flow associated with an IC manufacturing system 1000 discussed below with respect to FIG. 10. In some embodiments, one or more of FIGS. 1A-6 is some or all of an IC layout diagram generated by executing some or all of the operations of a method 800 discussed below with respect to FIG. 8. Accordingly, each of FIGS. 1A-6 represents a plan or cross-sectional view of both an IC layout diagram and a corresponding IC device.

Each of the figures herein, e.g., FIGS. 1A-6, is simplified for the purpose of illustration. The figures are views of IC structures and devices with various features included and excluded to facilitate the discussion below. In various embodiments, an IC structure, device and/or layout diagram includes one or more features corresponding to power distribution structures, metal interconnects, contacts, vias, gate structures, source/drain (S/D) structures, or other transistor elements, isolation structures, or the like, in addition to the features depicted in FIGS. 1A-6.

The positioning and relative sizes of the various features depicted in FIGS. 1A-6 are non-limiting examples provided for the purpose of illustration. In various embodiments, the IC layouts/devices depicted in FIGS. 1A-6 include features otherwise positioned and/or sized within the corresponding IC layouts/devices.

FIGS. 1A and 1B are respective plan and cross-sectional (along line A-A′ of FIG. 1A) views of an IC layout 100 and corresponding IC device 100, in accordance with some embodiments. FIG. 2A is a plan view of an IC layout 200A and corresponding IC device 200A, in accordance with some embodiments, and FIGS. 2B and 2C are respective plan and cross-sectional (along line B-B′ of FIG. 2B) views of an IC layout 200B and corresponding IC device 100B, in accordance with some embodiments. IC layouts and corresponding devices 200A and 200B are collectively referred to as IC layout 200 and IC device 200 in some embodiments.

In addition to the views of IC layout/device 100 or 200, each of FIGS. 1A, 2A, and 2B includes X and Y directions, and each of FIGS. 1B and 2C includes the Y direction and a Z direction.

Each of IC layout/device 100 and 200 includes a portion of a semiconductor substrate SUB, also referred to as a substrate SUB, a semiconductor wafer SUB, or wafer SUB in some embodiments. Substrate SUB includes a front side (Frontside) and a back side (Backside), each corresponding to a subset of the features included in IC layout/device 100 or 200, as depicted in FIGS. 1A-3 and discussed below.

IC layout/device 100 corresponds to embodiments in which a cell 100C includes two instances of an active region/area AA1 and an instance of an active region/area AA2, and IC layout/device 200 corresponds to embodiments in which a cell 200AC or 200BC includes two instances of active region/area AA2. In some embodiments, cell 100C is referred to as a PNNP, PNP, NPPN, or NPN cell, and/or cell 200AC or 200BC, referred to collectively as cell 200C in some embodiments, is referred to as a PPNN or NNPP cell.

Each of cells 100C and 200C also includes instances of MD regions/segments MD, cut-MD regions CMD, gate regions/structures GS, cut-gate regions CP, feed-through via (FTV) regions/structures FTV, back-side via regions/structures VB, and via regions/structures VDR, and in some embodiments via regions/structures VD and/or VG, configured as discussed below.

Each of IC layouts/devices 100 and 200 also includes instances of front-side metal regions/segments M0A and M0B, also referred to as front-side metal zero regions/segments MOA and M0B or metal zero regions/segments M0A and M0B in some embodiments, and instances of back-side metal regions/segments BM0A and BM0B, also referred to as back-side metal zero regions/segments BM0A and BM0B, back-side power rails BM0A and BM0B, or power rails BM0A and BM0B in some embodiments. In some embodiments, one or more of front-side metal regions/segments M0A and/or M0B, and/or back-side metal regions/segments BM0A and/or BM0B is included in a corresponding one or more of cells 100C or 200C.

In some embodiments, front-side metal regions/segments M0A and M0B correspond to separate front-side mask sets, e.g., configured to enable a metal region/segment pitch PO to be smaller than a metal region/segment pitch based on a single mask set.

In some embodiments, back-side metal regions/segments BM0A and BM0B correspond to separate back-side mask sets, e.g., configured as separate distribution paths for power supply and reference voltages.

In FIGS. 1A-6, not all instances of each feature are labeled; in some cases, fewer than all instances, e.g., a single instance, of a given feature are labeled for the purpose of clarity.

An active region/area, e.g., an active region/area AA1 or AA2, is a region in the IC layout diagram included in the manufacturing process as part of defining an active area, also referred to as an oxide diffusion or definition (OD), in substrate SUB, either directly or in an n-well or p-well (not shown), in which one or more IC device features, e.g., a S/D structure (not shown), is formed.

In some embodiments, an active area is an n-type or p-type active area of a planar transistor, a fin field-effect transistor (FinFET), or a gate-all-around (GAA) transistor. In various embodiments, an active area (structure) includes one or more of a semiconductor material, e.g., silicon (Si), silicon-germanium (SiGe), silicon-carbide (SiC), or the like, an acceptor dopant, e.g., boron (B) or aluminum (Al), or a donor dopant, e.g., phosphorous (P) or arsenic (As), or another suitable material.

In some embodiments, an active region/area is a region in an IC layout diagram included in the manufacturing process as part of defining a nano-sheet structure, e.g., an epitaxial region of a continuous volume of one or more layers of one or more semiconductor materials having either n-type or p-type doping. In various embodiments, individual nano-sheet layers include a single monolayer or multiple monolayers of a given semiconductor material.

In some embodiments, a portion of an active region/area, e.g., an epitaxial region, corresponds to a S/D structure (also referred to as a S/D terminal in some embodiments) of a transistor. In some embodiments, an active region/area includes one or more channel regions, e.g., a channel CL, portions of the active region/area such as epitaxial regions, extending through a gate structure and between the S/D terminals of the transistor, e.g., a GAA transistor, thereby being configured as a conduction path between the S/D terminals controllable by the gate structure.

A gate region/structure, e.g., a gate region/structure GS, is a region in the IC layout diagram included in the manufacturing process as part of defining a gate structure. A gate structure is a volume including one or more conductive segments, e.g., a gate electrode, including one or more conductive materials, e.g., polysilicon, copper (Cu), aluminum (Al), tungsten (W), cobalt (Co), ruthenium (Ru), or one or more other metals or other suitable materials, substantially surrounded by one or more insulating materials, the one or more conductive segments thereby being configured to control a voltage provided at an adjacent gate dielectric layer.

A dielectric layer, e.g., a gate dielectric layer, is a volume including one or more insulating materials, e.g., silicon dioxide, silicon nitride (Si₃N₄), and/or one or more other suitable material such as a low-k material having a k value less than 3.8 or a high-k material having a k value greater than 3.8 such as aluminum oxide (Al₂O₃), hafnium oxide (HfO₂), tantalum pentoxide (Ta₂O₅), or titanium oxide (TiO₂), suitable for providing a high electrical resistance between IC structure elements, i.e., a resistance level above a predetermined threshold corresponding to one or more tolerance levels of a resistance-based effect on circuit performance.

In various embodiments, a gate dielectric layer has a substantially planar shape, e.g., as part of a planar transistor, a shape corresponding to a transistor topography, e.g., as part of a FinFET, or a substantially cylindrical shape, e.g., as part of a GAA transistor, whereby the gate electrode is separated from a corresponding channel region by a distance sufficiently large to limit current flow to a specified level, and sufficiently small to enable generation of an electric field in the channel having a specified field strength.

A cut-gate region, e.g., a cut-gate region CP, also referred to as a cut-poly region in some embodiments, is a region in the IC layout diagram included in the manufacturing process as part of defining a discontinuity in the gate electrode of a given gate structure, e.g., a portion etched away after the gate electrode has been deposited, thereby electrically isolating the corresponding adjacent portions of the gate electrode from each other.

An MD region/segment, e.g., an MD region/segment MD, is a conductive region in the IC layout diagram included in the manufacturing process as part of defining an MD segment, also referred to as a conductive segment or MD conductive line or trace, in and/or on the semiconductor substrate and capable of being electrically connected to an underlying S/D structure and/or underlying and/or overlying via structure. In some embodiments, an MD segment includes a portion of at least one metal layer, e.g., a contact layer, overlying and contacting the substrate and having a thickness sufficiently small to enable formation of an insulation layer between the MD segment and an overlying metal layer, e.g., a first or lowermost metal layer. In various embodiments, an MD segment includes one or more of copper (Cu), silver (Ag), tungsten (W), titanium (Ti), nickel (Ni), tin (Sn), aluminum (Al) or another metal or material suitable for providing a low resistance electrical connection between IC structure elements, i.e., a resistance level below a predetermined threshold corresponding to one or more tolerance levels of a resistance-based effect on circuit performance.

In various embodiments, an MD segment includes a section of substrate SUB and/or an epitaxial layer having a doping level, e.g., based on an implantation process, sufficient to cause the segment to have the low resistance level. In various embodiments, a doped MD segment includes one or more dopant materials having doping concentrations of about 1*10¹⁶ per cubic centimeter (cm⁻³) or greater.

In some embodiments, a manufacturing process includes multiple MD layers, and an MD region/segment refers to any one or more of the multiple MD layers in the manufacturing process.

A cut-MD region, e.g., a cut-MD region CMD, is a region in the IC layout diagram included in the manufacturing process as part of defining a discontinuity in a given MD structure, e.g., a portion etched away after the MD structure has been formed, thereby resulting in adjacent and aligned MD segments electrically isolated from each other.

A metal region/segment, e.g., a front-side metal region/segment M0A or M0B or a back-side metal region/segment BM0A or BM0B, is a region in the IC layout diagram included in the manufacturing process as part of defining a metal segment structure including one or more conductive materials, e.g., polysilicon, copper (Cu), aluminum (Al), tungsten (W), cobalt (Co), ruthenium (Ru), or one or more other metals or other suitable materials, in a given metal layer of the manufacturing process.

In some embodiments, each of front-side metal regions/segments M0A and M0B corresponds to a lowermost, or first, front-side metal layer, also referred to as a metal zero layer or front-side metal zero layer in some embodiments. In some embodiments, each of metal regions/segments BM0A and BM0B corresponds to a lowermost, or first, back-side metal layer, also referred to as a back-side metal zero layer in some embodiments. Front-side metal regions/segments M0A and M0B and/or back-side metal regions/segments BM0A and BM0B corresponding to other metal layers are within the scope of the present disclosure.

A via region/structure, e.g., a via region/structure FTV, VB, VDR, VD, or VG, is a region in the IC layout diagram included in the manufacturing process as part of defining a via structure including one or more conductive materials configured to provide an electrical connection between a first conductive structure, e.g., a power rail or other metal segment, and a second conductive structure. In some embodiments, a first or second conductive structure is referred to as an overlying conductive structure or an underlying conductive structure. In some embodiments, the second structure corresponds to an MD structure in the case of a via region/structure FTV or VDR, a S/D structure or other epitaxial region in the case of a via region/structure VB or VD, and/or a gate electrode in the case of a via region/structure VG.

As depicted in FIGS. 1A-2C, IC layouts/devices 100 and 200 include respective cells 100C and 200C having a cell height CH corresponding to 13 locations, e.g., tracks, along the Y direction at which up to seven instances of metal regions/segments M0A are capable of being alternatively positioned with up to six instances of metal regions/segments M0B. Other relationships between cell height CH and instances of metal regions/segments M0A and M0B are within the scope of the present disclosure.

As depicted in FIGS. 1A, 1B, 2B, and 2C, top and bottom (with respect to the Y direction) borders of cell 100C and 200BC are aligned with centers (with respect to the Y direction) of metal regions/segments M0A and BM0A in the X direction, and a center of an instance of metal region/segment M0A is aligned with a center of metal region/segment BM0B in the X direction at a center of the corresponding cell 100C or 200BC.

As depicted in FIG. 2A, top and bottom borders of cell 200AC are aligned with centers of metal regions/segments M0A in the X direction, and instances of metal region/segment M0A are aligned with top edges of metal regions/segments BM0A and BM0B.

As depicted in FIGS. 1A and 1B, each active region/area AA1 of IC layout/device 100 overlaps/overlies two via regions/structures VB, each of which overlaps/overlies a corresponding metal region/segment BMOA, and active area/region AA2 overlaps/overlies two via regions/structures VB, each of which overlaps/overlies metal region/segment BM0B.

At each location at which an active region/area AA1 overlaps/overlies a via region/structure VB, an MD region/segment MD overlaps/overlies the active region/area AA1 and extends away from the active region/area AA1 in the corresponding positive or negative Y direction. For each active region/area AA1, the two corresponding MD regions/segments MD overlap/overlie a via region/structure FTV, which overlaps/overlies the metal region/segment BM0A overlapped/overlaid by the active region/area AA1.

Each such front-side MD region/segment MD is thereby electrically connected to the corresponding underlying back-side metal region/segment BM0A through a parallel configuration of a corresponding via region/structure FTV and the corresponding portion of active region/area AA1 in series with the corresponding via region/structure VB. In some embodiments, the parallel configuration is referred to as a dual-via configuration or a dual-via frontside/backside connection.

In the embodiment depicted in FIGS. 1A and 1B, the via regions/structures VB included in the dual-via configuration overlap/overlie edges of metal regions/segments BMOA. In some embodiments, one or more of the via regions/structures VB included in the dual-via configuration overlap/overlie metal regions/segments BM0A at locations other than an edge.

In the embodiment depicted in FIGS. 1A and 1B, the via regions/structures FTV included in the dual-via configuration overlap/underlie edges of the corresponding MD regions/segments MD. In some embodiments, one or more of the via regions/structures FTV included in the dual-via configuration overlap/underlie the corresponding MD regions/segments MD at locations other than an edge.

In the embodiment depicted in FIGS. 1A and 1B, IC layout/device 100 includes two metal regions/segments M0A that overlap/overlie corresponding via regions/structures VDR, which overlap/overlie corresponding ones of the MD regions/segments MD electrically connected to overlapping/underlying metal regions/segments BM0A through dual-via configurations. In some embodiments, IC layout/device 100 does not include one or both of metal regions/segments MOA electrically connected to metal regions/segments BM0A through dual-via configurations.

In the embodiment depicted in FIGS. 1A and 1B, IC layout/device 100 includes a metal region/segment M0A that overlaps/overlies corresponding via regions/structures VDR, which overlap/overlie corresponding ones of MD regions/segments MD, which overlap/overlie corresponding portions of active region/area AA2, which overlap/overlie corresponding via regions/structures VB, which overlap/overlie metal region/structure BM0B, the metal region/segment M0A thereby being electrically connected to overlapping/underlying metal region/segment BM0A through a single-via configuration. In some embodiments, IC layout/device 100 does not include some or all of the metal region/segment M0A to metal region/segment BM0B electrical connection.

As depicted in FIGS. 2A-2C, each active region/area AA2 of IC layouts/devices 200A and 200B overlaps/overlies two via regions/structures VB, each of which overlaps/overlies a corresponding metal region/segment BM0A or BM0B.

At each location at which an active region/area AA2 overlaps/overlies a via region/structure VB, an MD region/segment MD overlaps/overlies the active region/area AA2 and extends away from the active region/area AA2 in the corresponding positive or negative Y direction. For each active region/area AA2, the two corresponding MD regions/segments MD overlap/overlie a via region/structure FTV, which overlaps/overlies the metal region/segment BM0A or BM0B overlapped/overlaid by the active region/area AA2.

Each such front-side MD region/segment MD is thereby electrically connected to the corresponding underlying back-side metal region/segment BM0A or BM0B through a parallel configuration of a corresponding via region/structure FTV and the corresponding portion of active region/area AA2 in series with the corresponding via region/structure VB. In some embodiments, the parallel configuration is referred to as a dual-via configuration or a dual-via frontside/backside connection.

In the embodiment of IC layout/device 200B depicted in FIGS. 2B and 2C, the via regions/structures VB included in the dual-via configuration overlap/overlie edges of metal regions/segments BM0A and BM0B. In some embodiments, one or more of the via regions/structures VB included in the dual-via configuration of IC layout/device 200B overlap/overlie metal regions/segments BM0A or BM0B at locations other than an edge.

In the embodiment depicted in FIGS. 2B and 2C, IC layout/device 200B includes three metal regions/segments M0A that overlap/overlie corresponding via regions/structures VDR, which overlap/overlie corresponding ones of the MD regions/segments MD electrically connected to overlapping/underlying metal regions/segments BM0A and BM0B through dual-via configurations. In some embodiments, IC layout/device 100 does not include one or both of metal regions/segments M0A electrically connected to metal regions/segments BM0A and BM0B through dual-via configurations.

In some embodiments of IC layouts/devices 100 and/or 200, metal regions/segments BM0A and the corresponding instances of metal region/segment MOA, if present, are configured to have one of a power supply or reference voltage, and metal regions/segments BM0B and the corresponding instances of metal region/segment MOA, if present, are configured to have the other of the power supply or reference voltage.

As depicted in FIGS. 1A and 2A, in the Y direction, active region/area AA1 has a width D1, active region/area AA2 has a width D2, a spacing between adjacent instances of active regions/areas AA1 and AA2 has a distance D3, a spacing from a top border of cell 100C or 200AC to an active region/area AA1 or AA2 has a distance D3a, a spacing from a bottom border of cell 100C or 200AC to an active region/area AA1 or AA2 has a distance D3b, cut-gate region CP has a width D4, via region/structure FTV has a width D5, via regions/structures VB corresponding to active regions/areas AA1 and AA2 have respective widths D6a and D6b, and metal regions/segments BM0A and BM0B have respective widths D7a and D7b.

As depicted in FIG. 1A, cell height CH of cell 100C is given by

$$CH = 2 \times D 1 + D 2 + 2 \times D 3 + D 3 a + D 3 b . \qquad ( 1 )$$

As depicted in FIG. 2A, cell height CH of cell 200AC is given by

$$CH = 2 \times D 2 + D 3 + D 3 a + D 3 b . \qquad ( 2 )$$

In some embodiments, width D2 is equal to approximately twice width D1.

In some embodiments, widths D7a and D7b are approximately equal or width D7a is greater than width D7b.

In some embodiments, two values, e.g., widths and/or distances, are considered to be approximately related based on being nominal values corresponding to an IC layout and/or based on being values within one or more tolerance ranges corresponding to a manufacturing process associated with an IC device.

Because signal paths are routed to a given cell through metal regions/segments M0A and M0B, the relationships of the Y direction widths and distances to metal region/segment pitch PO can affect signal path routing efficiency. In some embodiments, routing efficiency improves as a ratio of a Y direction width or distance to pitch PO decreases.

In some embodiments, one or more of a ratio of cell height CH to pitch PO ranges from ten to fifteen, a ratio of width D1 or D2 to pitch PO ranges from one to five, a ratio of distance D3, D3a, or D3b to pitch PO ranges from two to five, a ratio of width D4 to pitch PO ranges from one to four, a ratio of width D5 to pitch PO ranges from one to two, a ratio of width D6a or D6b to pitch PO ranges from one to five, or a ratio of width D7a or D7b to pitch PO ranges from one to ten.

In some embodiments of IC layouts/devices 100 or 200, one or more of cells 100C, 200AC, or 200BC includes instances of active regions/areas AA1 or AA2, MD regions/segments MD, cut-MD regions CMD, gate regions/structures GS, cut-gate regions CP, vias VD or VG, or metal regions/segments M0A or M0B configured as one or more transistors TX (a single instance labeled in each of FIGS. 1A and 2A for clarity) at locations at which a gate region/structure GS overlaps/overlies an active region/area AA1 or AA2.

At such locations, one or more channels CL extend between adjacent epitaxial regions of the active region/area and through the gate electrode of the gate region/structure GS.

In some embodiments, a leftmost and/or rightmost (with respect to the X direction) gate region/structure GS of a cell 100C, 200AC, or 200BC is a dummy gate region/structure, e.g., a gate region/structure that overlaps/overlies edges of active regions/areas AA1 and/or AA2.

In the embodiments depicted in FIGS. 1A-2C, cells 100C and 200C of IC layouts/devices 100 and 200 include two or four gate regions/structures GS extending in the Y direction. Cells 100C and 200C of IC layouts/devices 100 and 200 including other numbers of gate regions/structures GS extending in the Y direction are within the scope of the present disclosure.

By including instances of via regions/structures VB and FTV configured as discussed above, each of IC layouts/devices 100, 200A, and 200B includes electrical paths from power rails BM0A and/or BM0B to corresponding MD segments including parallel arrangements of the two via structures whereby the dual-via path resistance is reduced compared to approaches in which electrical paths from power rails to front-side structures do not include parallel arrangements of via structures.

The reduced path resistance acts to reduce parasitic voltage drops due to current flow, i.e., IR voltage drops, compared to such other approaches. In some embodiments, an IR drop is reduced by approximately 5 millivolts (mV) compared to other approaches.

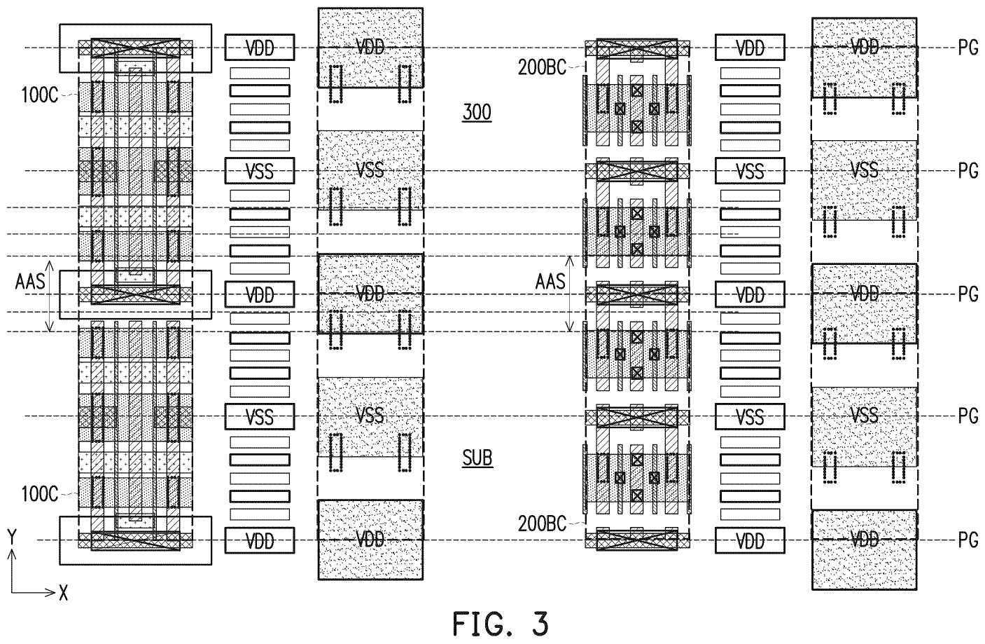

FIG. 3 depicts IC layout/device 300, in accordance with some embodiments. IC layout/device 300 includes two instances each of cells 100C and 200BC, discussed above with respect to FIGS. 1A-2C, aligned in the Y direction, and power grid tracks PG extending in the X direction. Individual features of cells 100C and 200BC are not labeled for the purpose of clarity.

The numbers of instances of cells 100C and 200BC are non-limiting examples provided for the purpose of illustration. Other numbers of instances of one or both of cells 100C or 200BC, e.g., zero, one, or more than two, are within the scope of the present disclosure.

Alternating instances of power grid tracks PG correspond to power supply voltage VDD and reference voltage VSS.

In the embodiment depicted in FIG. 3, power grid tracks corresponding to power supply voltage VDD are aligned with shared borders of cells 100C and 200BC, and power grid tracks corresponding to reference voltage VSS are aligned with centers of cells 100C and 200BC. In such embodiments, active regions/areas AA1 and AA2 of cells 100C are respective p-type and n-type active regions/areas, and cells 100C are referred to as PNP or PNNP cells 100C in some embodiments. In such embodiments, top and bottom instances of active regions/areas AA2 of cells 200BC are respective p-type and n-type active regions/areas, and cells 200BC are referred to as PPNN cells 200BC in some embodiments.

In some embodiments, power grid tracks corresponding to reference voltage VSS are aligned with shared borders of cells 100C and 200BC, and power grid tracks corresponding to power supply voltage VDD are aligned with centers of cells 100C and 200BC. In such embodiments, active regions/areas AA1 and AA2 of cells 100C are respective n-type and p-type active regions/areas, and cells 100C are referred to as NPN or NPPN cells 100C in some embodiments. In such embodiments, top and bottom instances of active regions/areas AA2 of cells 200BC are respective n-type and p-type active regions/areas, and cells 200BC are referred to as NNPP cells 200BC in some embodiments.

As depicted in FIG. 3, adjacent active regions/areas AA1 at the shared borders of cells 100C and adjacent active regions/areas AA2 at the shared borders of cells 200BC are separated by a spacing AAS. In some embodiments, spacing AAS corresponds to one or more minimum spacing rules associated with the positioning of via region/structure FTV between the adjacent active regions/areas AA1 or AA2. In some embodiments, spacing AAS has a minimum value equal to a sum of width D5 of via region/structure FTV, discussed above with respect to FIGS. 1A and 2A, plus twice a minimum spacing between via region/structure FTV and a given instance of active region/area AA1 or AA2. In some embodiments, spacing AAS has a value equal to a sum of distances D3a and D3b, discussed above with respect to FIGS. 1A and 2A.

In some embodiments, spacing AAS has a value greater than a spacing between adjacent active regions/areas of cells (not shown) that do not include a via region/structure FTV. In some embodiments, cells 100C or 200C are modified versions of previously existing cells in which distances D3a and D3b, and thereby values of spacing AAS, have been increased to accommodate placement of via regions/structures FTV at shared cell borders.

As values of spacing AAS increase, the flexibility to accommodate widths D5 of via region/structure FTV increases while the flexibility to accommodate widths D1 and D2 of active regions areas AA1 and AA2 and distance D3 between instances active regions/areas AA1 and AA2 decreases. In some embodiments, spacing AAS has a value ranging from 80 nanometers (nm) to 150 nm. In some embodiments, spacing AAS has a value ranging from 100 nm to 120 nm.

By including one or more of cells 100C or 200BC configured as discussed above to include corresponding dual-via paths, IC layout/device 300 is capable of realizing the benefits discussed above with respect to IC layouts/devices 100 and 200.

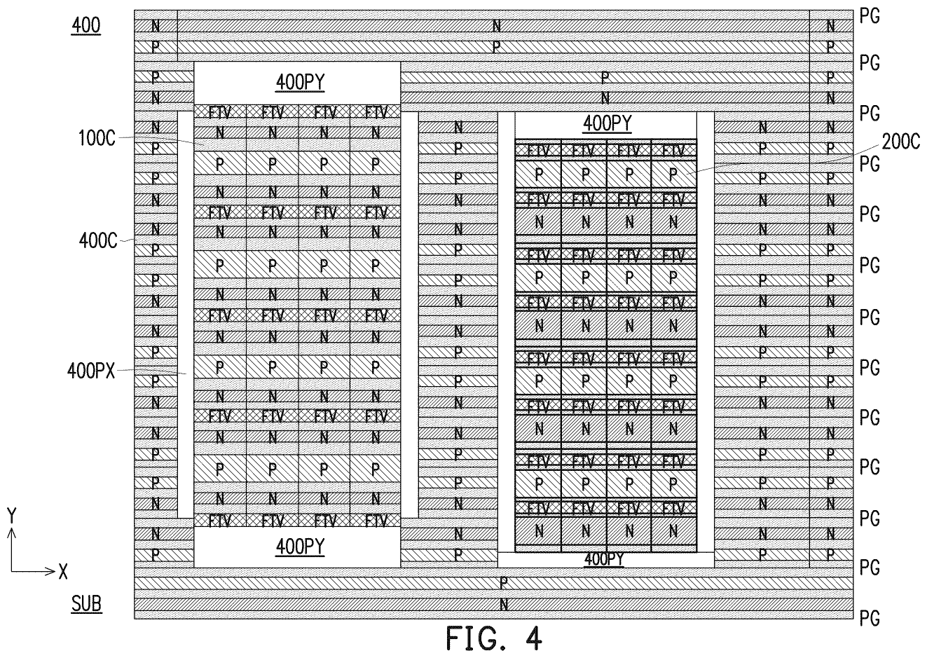

FIG. 4 depicts IC layout/device 400, in accordance with some embodiments. IC layout/device 400 includes blocks of four rows and four columns each of cells 100C and 200C aligned with power grid tracks PG, each discussed above with respect to FIG. 1A-3. Each block is surrounded by instances of cells 400C arranged in rows aligned with power grid tracks PG in the Y direction.

The numbers of rows and columns of cells 100C and 200C are non-limiting examples provided for the purpose of illustration. Other numbers of rows and/or columns of one or both of cells 100C or 200C, e.g., zero, one through three, or more than four, are within the scope of the present disclosure.

Each block of cells 100C or 200C is separated in the X direction from cells 400C by padding cells 400PX, separated in the Y direction from cells 400C by padding cells 400PY. Individual features of cells 100C, 200C, 400PX, and 400PY are not shown for the purpose of clarity.

Cells 400C are IC layouts that are free from including parallel arrangements of via structures between front-side and back-side metal region/segments. In the embodiment depicted in FIG. 4, cells 400C include single instances of n-type and p-type active regions/areas N and P, and have a cell height equal to a pitch of power grid tracks PG (not labeled). In some embodiments, cells 400C include one or more arrangements other than that depicted in FIG. 4, e.g., a cell height equal to twice the pitch of power grid tracks PG.

Each of padding cells 400PX and 400PY is one or more cells configured to physically separate, and thereby electrically isolate, the corresponding block of cells 100C or 200C from cells 400C along the corresponding positive or negative X or Y direction.

In various embodiments, a single instance of cell 400PX corresponds to one or more rows of cells 100C or 200C and/or a single instance of cell 400PY corresponds to one or more columns of cells 100C or 200C.

In some embodiments, cells 400PX and/or 400PY include features that include one or more insulating materials. In some embodiments, cells 400PX and/or 400PY have dimensions and/or include features positioned whereby a pattern uniformity, e.g., a gate pitch, is maintained between a block of cells 100C or 200C and adjacent cells 400C.

In some embodiments, cells 400PX and/or 400PY include features that include one or more dummy active regions, also referred to as dummy OD regions in some embodiments. A dummy active region/area is a region in an IC layout diagram included in the manufacturing process as part of defining an area in which a variation of the standard operations corresponding to forming an active area are performed. In some embodiments, the variations include a subset of and/or one or more operations in addition to the standard operations, e.g., a deposition operation, whereby the area includes one or more insulating materials instead of an active area.

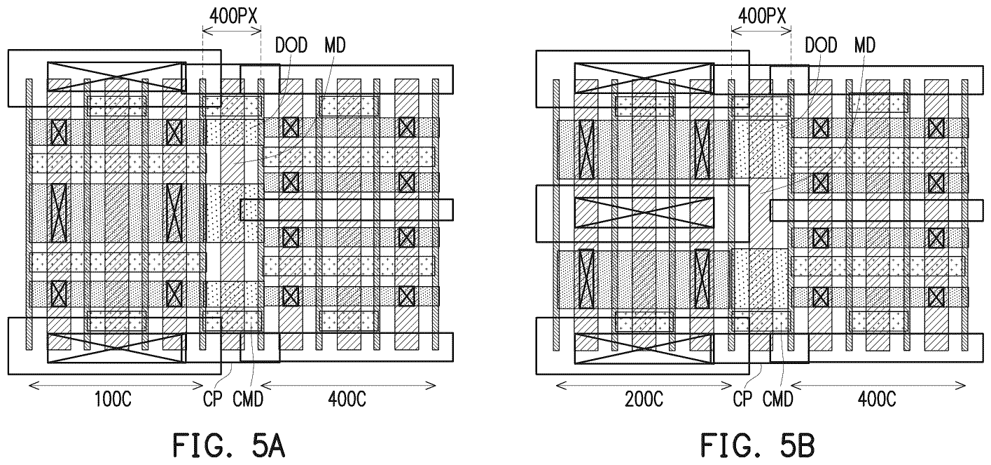

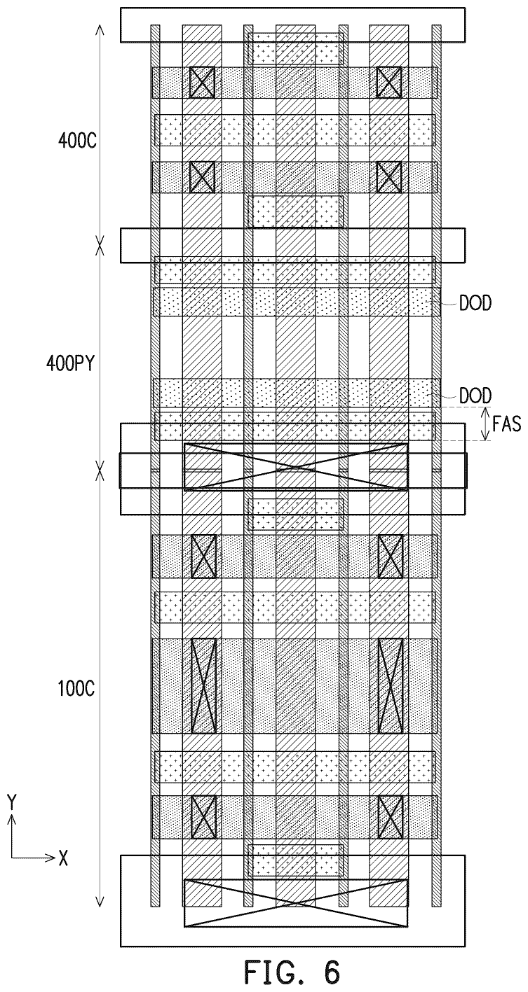

In some embodiments, a cell 400PX corresponds to the non-limiting example discussed below with respect to FIGS. 5A and 5B. In some embodiments, a cell 400PY corresponds to the non-limiting example discussed below with respect to FIG. 6.

By including one or more of cells 100C or 200C configured as discussed above to include corresponding dual-via paths, IC layout/device 400 is capable of realizing the benefits discussed above with respect to IC layouts/devices 100 and 200.

FIGS. 5A and 5B depict non-limiting examples of cells 400PX and 400C, discussed above with respect to FIG. 4. In the embodiment depicted in FIG. 5A, cell 400PX is positioned between cell 400C and cell 100C, discussed above with respect to FIGS. 1A and 1B. In the embodiment depicted in FIG. 5B, cell 400PX is positioned between cell 400C and cell 200C, discussed above with respect to FIGS. 2A-2C. Individual features of cells 100C, 200C, and 400C are not labeled for the purpose of clarity.

As depicted in each of FIGS. 5A and 5B, cell 400PX has a width in the X direction equal to a gate pitch (not labeled) and includes instances of dummy active region/area DOD, an MD region/segment MD, and instances of cut-MD region CMD and cut-gate region CP.

Dummy active regions/areas DOD are aligned in the X direction with active regions/areas, e.g., active regions/areas AA1 and/or AA2, of cell 100C or 200C, and extend across cell 400PX. Dummy active regions/areas DOD are thereby configured to electrically isolate cell 100C and 200C active regions/areas from active regions/areas of cell 400C. In some embodiments, dummy active regions/areas DOD being aligned in the X direction with active regions/areas of cell 100C or 200C act to maintain loading uniformity of one or more pieces of manufacturing equipment used to form active areas in IC device 400.

MD region/segment MD extends in the Y direction and is centered in cell 400PX along the X direction. MD region/segment MD is thereby configured to match an MD spacing pattern of cell 100C or 200C with that of cell 400C whereby manufacturing loading uniformity is maintained.

Cut-MD regions CMD and cut-gate regions CP are configured to electrically isolate instances of via region/structure FTV from features of cell 400C.

IC layout/device 400 including one or both of the non-limiting examples of cell 400PX between cell 400C and the corresponding one of cell 100C or 200C is thereby capable of realizing the benefits discussed above.

FIG. 6 depicts a non-limiting example of cell 400PY, discussed above with respect to FIG. 4, positioned between cell 400C and cell 100C, discussed above with respect to FIGS. 1A and 1B.

Individual features of cells 100C and 400C are not labeled for the purpose of clarity. In some embodiments (not shown), the non-limiting example of cell 400PY is positioned between cell 400C and cell 200C, discussed above with respect to FIGS. 2A-2C.

As depicted in FIG. 6, cell 400PY includes instances of dummy active region/area DOD, MD region/segment MD, cut-MD region CMD, and gate structure GS, each discussed above with respect to FIGS. 1A-3.

The numbers of instances of active region/area DOD, MD region/segment MD, cut-MD region CMD, and gate structures GS depicted in FIG. 6 are non-limiting examples provided for the purpose of illustration. Numbers of instances of active region/area DOD, MD region/segment MD, cut-MD region CMD, and gate structures GS other than those depicted in FIG. 6 are within the scope of the present disclosure.

The instances of MD region/segment MD and gate region/structure GS extend in the Y and are configured to align with corresponding instances of MD region/segment MD and gate region/structure GS in cells 400C and 100C or 200C, thereby acting to maintain manufacturing loading uniformity.

Cut-MD regions CMD and cut-gate regions CP are configured to electrically isolate the instances of MD region/segment MD and gate region/structure GS in cell 400PX from features in cells 400C and 100C or 200C, e.g., via region/structure FTV in cell 100C, from each other.

The instances of dummy active region/area DOD are configured to electrically isolate the instances of MD region/segment MD and gate region/structure GS in cell 400PX from features in cells 400C and 100C or 200C, e.g., via region/structure FTV in cell 100C, from each other. In some embodiments, the instances of dummy active region/area DOD are configured to match active region/area spacing patterns of cells 400C and 100C or 200C whereby manufacturing loading uniformity is maintained.

As depicted in FIG. 6, via region/structure FTV, e.g., in cell 100C, and adjacent dummy active region/area DOD are separated by a spacing FAS. In some embodiments, because the dummy active region/area DOD is configured to electrically isolate via region/structure FTV from other features, spacing FAS is smaller than a minimum spacing rule for a spacing between an instance of via region/structure FTV and an active region/area.

IC layout/device 400 including the non-limiting example of cell 400PY between cell 400C and one of cell 100C or 200C is thereby capable of realizing the benefits discussed above.

FIG. 7 is a flowchart of a method 700 of manufacturing an IC device, in accordance with some embodiments. Method 700 is operable to form some or all of IC device 100 discussed above with respect to FIGS. 1A and 1B, IC device 200 discussed above with respect to FIGS. 2A-2C, IC device 300 discussed above with respect to FIG. 3, and/or IC device 400 discussed above with respect to FIGS. 4-6.

In some embodiments, performing some or all of the operations of method 700 is part of building a plurality of IC devices, e.g., transistors, logic gates, memory cells, interconnect structures, and/or other suitable devices, by performing a plurality of manufacturing operations, e.g., one or more of a lithography, diffusion, deposition, etching, planarizing, or other operation suitable for building the plurality of IC devices in a semiconductor wafer.

In some embodiments, the operations of method 700 are performed in the order depicted in FIG. 7. In some embodiments, the operations of method 700 are performed in an order other than the order depicted in FIG. 7. In some embodiments, one or more additional operations are performed before, during, and/or after the operations of method 700. In some embodiments, performing some or all of the operations of method 700 includes performing one or more operations as discussed below with respect to IC manufacturing system 1000 and FIG. 10.

At operation 702, in some embodiments, first and second epitaxial regions are formed on a front side of a semiconductor wafer. In some embodiments, forming the first and second epitaxial regions includes forming one of active areas AA1 or AA2 of IC device 100 or 200, discussed above with respect to FIGS. 1A-6.

In some embodiments, forming the first and second epitaxial regions includes forming two or more additional epitaxial regions, e.g., included in one or both of active areas AA1 or AA2 of a same IC device 100 or 200 and/or one or both of active areas AA1 or AA2 of one or more additional IC devices 100 or 200, as discussed above with respect to FIGS. 1A-6.

In some embodiments, forming two or more additional epitaxial regions includes forming the two or more additional epitaxial regions having a same or opposite doping as that of the first and second epitaxial regions, e.g., as discussed above with respect to FIGS. 1A-6.

In some embodiments, forming two or more additional epitaxial regions includes forming the two or more additional epitaxial regions having a same or different width as that of the first and second epitaxial regions, e.g., as discussed above with respect to FIGS. 1A-6.

In some embodiments, forming the first and second epitaxial regions includes performing one or more deposition and/or implantation processes in areas of a semiconductor wafer corresponding to the first and second epitaxial areas, whereby predetermined doping concentrations and types are achieved for one or more given dopants as discussed above with respect to FIGS. 1A-6.

In some embodiments, forming the first and second epitaxial regions includes forming S/D structures including the first and second epitaxial regions, e.g., by performing one or more implantation processes and/or one or more deposition processes.

At operation 704, in some embodiments, a first gate electrode and a first channel extending between the first and second epitaxial regions and through the first gate electrode are constructed.

In some embodiments, constructing the first gate electrode and first channel includes constructing one or more instances of gate structure GS and channel CL discussed above with respect to FIGS. 1A-6.

In some embodiments, constructing the first gate electrode and first channel includes constructing one or more additional gate electrodes and/or channels in accordance with forming two or more additional epitaxial regions in operation 702.

In some embodiments, constructing the first gate electrode and first channel includes performing a plurality of manufacturing operations, e.g., one or more of a lithography, diffusion, deposition, etching, planarizing, or other operation suitable for constructing the first gate electrode and first channel as discussed above with respect to FIGS. 1A-6.

At operation 706, in some embodiments, first and second MD segments directly overlying the respective first and second epitaxial regions are formed. In some embodiments, forming the first and second MD segments includes forming instances of MD segments MD discussed above with respect to FIGS. 1A-6.

In some embodiments, forming the first and second MD segments includes forming two or more additional MD segments in accordance with forming two or more additional epitaxial regions in operation 702.

In some embodiments, forming an MD segment includes performing a plurality of manufacturing operations including depositing and patterning one or more photoresist layers, performing one or more etching processes, and performing one or more deposition processes whereby one or more conductive materials are configured to form a continuous, low resistance structure.

In some embodiments, forming the first and second MD segments is part of forming one or more transistors, e.g., transistor TX discussed above with respect to FIGS. 1A-6.

In some embodiments, forming the first and second MD segments is part of forming one or more via structures and/or one or more metal segments, e.g., via structure VDR, VD, or VG, or metal segment M0A or M0B discussed above with respect to FIGS. 1A-6.

In some embodiments, forming a via structure or metal segment includes performing a plurality of manufacturing operations including depositing and patterning one or more photoresist layers, performing one or more etching processes, and performing one or more deposition processes whereby one or more conductive materials are configured to form a continuous, low resistance structure.

At operation 708, in some embodiments, a first via structure extending from the first epitaxial region to a back side of the semiconductor substrate is formed. In some embodiments, forming the first via structure includes forming via structure VB discussed above with respect to FIGS. 1A-6.

In some embodiments, forming the first via structure includes forming one or more additional via structures in accordance with forming two or more additional epitaxial regions in operation 702.

At operation 710, in some embodiments, a second via structure extending from the first MD segment to the back side of the semiconductor substrate is formed. In some embodiments, forming the second via structure includes forming via structure FTV discussed above with respect to FIGS. 1A-6.

In some embodiments, forming the second via structure includes forming one or more additional via structures in accordance with forming two or more additional epitaxial regions in operation 702.

At operation 712, in some embodiments, a first power rail overlying each of the first and second via structures is constructed on the back side of the semiconductor substrate. In some embodiments, forming the first power rail includes forming metal segment BM0A or BM0B discussed above with respect to FIGS. 1A-6.

In some embodiments, constructing the first power rail includes constructing one or more additional power rails in accordance with forming two or more additional epitaxial regions in operation 702.

In some embodiments, forming a power rail includes performing a plurality of manufacturing operations including depositing and patterning one or more photoresist layers, performing one or more etching processes, and performing one or more deposition processes whereby one or more conductive materials are configured to form a continuous, low resistance structure on a back side of the substrate.

By performing some or all of the operations of method 700, an IC device is manufactured in which each of one or more electricals path from one or more power rails to one or more MD segments includes a parallel arrangement of the two via structures, thereby realizing the benefits discussed above with respect to IC devices 100-400.

FIG. 8 is a flowchart of a method 800 of generating an IC layout diagram, e.g., an IC layout diagram 100 discussed above with respect to FIGS. 1A and 1B, IC layout diagram 200 discussed above with respect to FIGS. 2A-2C, IC layout diagram 300 discussed above with respect to FIG. 3, and/or IC layout diagram 400 discussed above with respect to FIGS. 4-6, in accordance with some embodiments.

In some embodiments, generating the IC layout diagram includes generating the IC layout diagram corresponding to an IC device, e.g., an IC device 100-400 discussed above with respect to FIGS. 1-6, manufactured based on the generated IC layout diagram.

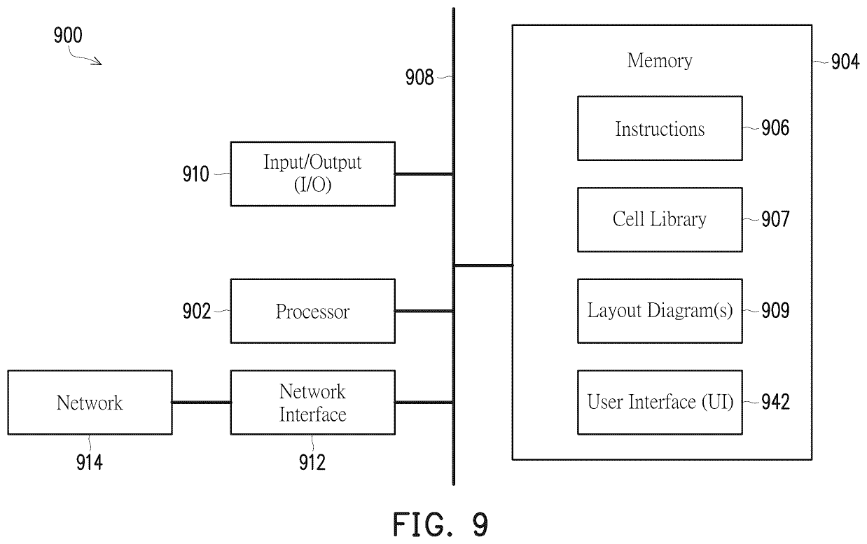

In some embodiments, some or all of method 800 is executed by a processor of a computer, e.g., a processor 902 of an IC layout diagram generation system 900, discussed below with respect to FIG. 9.

Some or all of the operations of method 800 are capable of being performed as part of a design procedure performed in a design house, e.g., a design house 1020 discussed below with respect to FIG. 10.

In some embodiments, the operations of method 800 are performed in the order depicted in FIG. 8. In some embodiments, the operations of method 800 are performed simultaneously and/or in an order other than the order depicted in FIG. 8. In some embodiments, one or more operations are performed before, between, during, and/or after performing one or more operations of method 800.

At operation 802, in some embodiments, a cell is obtained from a storage device, the cell including a dual-via configuration. The dual-via configuration includes first and second via regions configured as an electrical path including an arrangement of parallel via structures between a back-side power rail and at least one front-side feature, e.g., an MD region configured to define an MD segment. In some embodiments, the at least one front-side feature includes via and metal regions overlapping the MD region and corresponding to an overlying via structure and metal segment, e.g., via region/structure VDR and metal region/segment M0A or M0B discussed above with respect to FIGS. 1A-3.

In some embodiments, obtaining the cell from the storage device includes obtaining one or more of cells 100C and/or 200C discussed above with respect to FIGS. 1A-6.

In some embodiments, obtaining the cell from the storage device includes obtaining the cell previously stored including the dual-via configuration.

In some embodiments, obtaining the cell from the storage device includes modifying a previously stored cell by adding and/or modifying one or more features to obtain the dual-via configuration.

In some embodiments, adding the one or more features includes adding one or more via regions, e.g., via region FTV and/or VB discussed above with respect to FIGS. 1A-6.

In some embodiments, modifying the one or more features includes moving an active region to accommodate one or more via regions, e.g., active region AA1 and/or AA2 discussed above with respect to FIGS. 1A-6.

In some embodiments, obtaining the cell from the storage device includes obtaining the IC layout diagram of the cell from cell library 907 of IC layout diagram generation system 900, discussed below with respect to FIG. 9.

In some embodiments, obtaining the cell from the storage device includes storing a modified IC layout diagram of the cell in the same or a different storage device, e.g., cell library 907 of IC layout diagram generation system 900.

At operation 804, the dual-via cell is positioned in an IC layout diagram. In some embodiments, positioning the cell in the IC layout diagram includes positioning one or more of cells 100C or 200C in IC layout 100-400 discussed above with respect to FIGS. 1A-6.

In some embodiments, positioning the cell in the IC layout diagram includes aligning the cell according to a power grid, e.g., power grid tracks PG discussed above with respect to FIGS. 3 and 4.

In some embodiments, positioning the cell in the IC layout diagram includes arranging one or more blocks of cells including the cell in the IC layout diagram, e.g., block of cells 100C or 200C in IC layout 400 discussed above with respect to FIGS. 4-6.

In some embodiments, arranging one or more blocks of cells includes positioning one or more padding cells between the one or more blocks and other cells, e.g., padding cells 400PX and/or 400PY between the one or more blocks and cells 400C discussed above with respect to FIGS. 4-6.

At operation 806, in some embodiments, the IC layout diagram including the dual-via configuration cell is stored in a storage device. In some embodiments, storing the IC layout diagram in the storage device includes storing IC layout 100-400, discussed above with respect to FIGS. 1A-6, in the storage device.

In various embodiments, storing the IC layout diagram in the storage device includes storing the IC layout diagram in a non-volatile, computer-readable memory or a cell library, e.g., a database, and/or includes storing the IC layout diagram over a network. In some embodiments, storing the IC layout diagram in the storage device includes storing the IC layout diagram in layout diagrams 909 or over network 914 of IC layout diagram generation system 900, discussed below with respect to FIG. 9.

At operation 808, in some embodiments, one or more manufacturing operations are performed based on the IC layout diagram. In some embodiments, performing one or more manufacturing operations includes performing one or more lithographic exposures based on the IC layout diagram. Performing one or more manufacturing operations, e.g., one or more lithographic exposures, based on the IC layout diagram is discussed above with respect to FIG. 7 and below with respect to FIG. 10.

By executing some or all of the operations of method 800, an IC layout diagram is generated corresponding to an IC device in which each of one or more electricals path from one or more power rails to one or more MD segments includes a parallel arrangement of the two via structures, thereby realizing the benefits discussed above with respect to IC devices 100-400.

FIG. 9 is a block diagram of IC layout diagram generation system 900, in accordance with some embodiments. Methods described herein of designing IC layout diagrams in accordance with one or more embodiments are implementable, for example, using IC layout diagram generation system 900, in accordance with some embodiments.

In some embodiments, IC layout diagram generation system 900 is a general purpose computing device including a hardware processor 902 and a non-transitory, computer-readable storage medium 904. Storage medium 904, amongst other things, is encoded with, i.e., stores, computer program code 906, i.e., a set of executable instructions. Execution of instructions 906 by hardware processor 902 represents (at least in part) an EDA tool which implements a portion or all of a method, e.g., method 500 of generating an IC layout diagram described above with respect to FIG. 5 and/or method 700 of generating an IC layout diagram described above with respect to FIG. 7 (hereinafter, the noted processes and/or methods).

Processor 902 is electrically coupled to computer-readable storage medium 904 via a bus 908. Processor 902 is also electrically coupled to an I/O interface 910 by bus 908. A network interface 912 is also electrically connected to processor 902 via bus 908. Network interface 912 is connected to a network 914, so that processor 902 and computer-readable storage medium 904 are capable of connecting to external elements via network 914. Processor 902 is configured to execute computer program code 906 encoded in computer-readable storage medium 904 in order to cause IC layout diagram generation system 900 to be usable for performing a portion or all of the noted processes and/or methods. In one or more embodiments, processor 902 is a central processing unit (CPU), a multi-processor, a distributed processing system, an application specific integrated circuit (ASIC), and/or a suitable processing unit.

In one or more embodiments, computer-readable storage medium 904 is an electronic, magnetic, optical, electromagnetic, infrared, and/or a semiconductor system (or apparatus or device). For example, computer-readable storage medium 904 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 904 includes a compact disk-read only memory (CD-ROM), a compact disk-read/write (CD-R/W), and/or a digital video disc (DVD).

In one or more embodiments, computer-readable storage medium 904 stores computer program code 906 configured to cause IC layout diagram generation system 900 (where such execution represents (at least in part) the EDA tool) to be usable for performing a portion or all of the noted processes and/or methods. In one or more embodiments, computer-readable storage medium 904 also stores information which facilitates performing a portion or all of the noted processes and/or methods.

In one or more embodiments, computer-readable storage medium 904 stores cell library 907 of cells including such cells as disclosed herein, e.g., cells 100C, 200C, 400PX, and 400PY discussed above with respect to FIGS. 1-6.

In one or more embodiments, computer-readable storage medium 904 stores layout diagrams 909 including such IC layout diagrams as disclosed herein, e.g., IC layout diagrams 100-400, in accordance with some embodiments discussed above with respect to FIGS. 1-6

IC layout diagram generation system 900 includes I/O interface 910. I/O interface 910 is coupled to external circuitry. In one or more embodiments, I/O interface 910 includes a keyboard, keypad, mouse, trackball, trackpad, touchscreen, and/or cursor direction keys for communicating information and commands to processor 902.

IC layout diagram generation system 900 also includes network interface 912 coupled to processor 902. Network interface 912 allows system 900 to communicate with network 914, to which one or more other computer systems are connected. Network interface 912 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more IC layout diagram generation systems 900.

IC layout diagram generation system 900 is configured to receive information through I/O interface 910. The information received through I/O interface 910 includes one or more of instructions, data, design rules, libraries of standard cells, and/or other parameters for processing by processor 902. The information is transferred to processor 902 via bus 908. IC layout diagram generation system 900 is configured to receive information related to a UI through I/O interface 910. The information is stored in computer-readable medium 904 as user interface (UI) 942.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by IC layout diagram generation system 900. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 10 is a block diagram of IC manufacturing system 1000, and an IC manufacturing flow associated therewith, in accordance with some embodiments. In some embodiments, based on an IC layout diagram, at least one of (A) one or more semiconductor masks or (B) at least one component in a layer of a semiconductor integrated circuit is fabricated using manufacturing system 1000.

In FIG. 10, IC manufacturing system 1000 includes entities, such as a design house 1020, a mask house 1030, and an IC manufacturer/fabricator (“fab”) 1050, that interact with one another in the design, development, and manufacturing cycles and/or services related to manufacturing an IC device 1060. The entities in system 1000 are connected by a communications network. In some embodiments, the communications network is a single network. In some embodiments, the communications network is a variety of different networks, such as an intranet and the Internet.

The communications network includes wired and/or wireless communication channels. Each entity interacts with one or more of the other entities and provides services to and/or receives services from one or more of the other entities. In some embodiments, two or more of design house 1020, mask house 1030, and IC fab 1050 is owned by a single larger company. In some embodiments, two or more of design house 1020, mask house 1030, and IC fab 1050 coexist in a common facility and use common resources.

Design house (or design team) 1020 generates an IC design layout diagram 1022. IC design layout diagram 1022 includes various geometrical patterns, e.g., a cell 100C, 200C, 400PX, and/or 400PY and/or an IC layout diagram 100-400 discussed above with respect to FIGS. 1-6. The geometrical patterns correspond to patterns of metal, oxide, or semiconductor layers that make up the various components of IC device 1060 to be fabricated. The various layers combine to form various IC features. For example, a portion of IC design layout diagram 1022 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1020 implements a proper design procedure to form IC design layout diagram 1022. The design procedure includes one or more of logic design, physical design or place and route. IC design layout diagram 1022 is presented in one or more data files having information of the geometrical patterns. For example, IC design layout diagram 1022 can be expressed in a GDSII file format or DFII file format.

Mask house 1030 includes data preparation 1032 and mask fabrication 1044. Mask house 1030 uses IC design layout diagram 1022 to manufacture one or more masks 1045 to be used for fabricating the various layers of IC device 1060 according to IC design layout diagram 1022. Mask house 1030 performs mask data preparation 1032, where IC design layout diagram 1022 is translated into a representative data file (RDF). Mask data preparation 1032 provides the RDF to mask fabrication 1044. Mask fabrication 1044 includes a mask writer. A mask writer converts the RDF to an image on a substrate, such as a mask (reticle) 1045 or a semiconductor wafer 1053. The design layout diagram 1022 is manipulated by mask data preparation 1032 to comply with particular characteristics of the mask writer and/or requirements of IC fab 1050. In FIG. 10, mask data preparation 1032 and mask fabrication 1044 are illustrated as separate elements. In some embodiments, mask data preparation 1032 and mask fabrication 1044 can be collectively referred to as mask data preparation.

In some embodiments, mask data preparation 1032 includes optical proximity correction (OPC) which uses lithography enhancement techniques to compensate for image errors, such as those that can arise from diffraction, interference, other process effects and the like. OPC adjusts IC design layout diagram 1022. In some embodiments, mask data preparation 1032 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1032 includes a mask rule checker (MRC) that checks the IC design layout diagram 1022 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1022 to compensate for limitations during mask fabrication 1044, which may undo part of the modifications performed by OPC in order to meet mask creation rules.

In some embodiments, mask data preparation 1032 includes lithography process checking (LPC) that simulates processing that will be implemented by IC fab 1050 to fabricate IC device 1060. LPC simulates this processing based on IC design layout diagram 1022 to create a simulated manufactured device, such as IC device 1060. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1022.

It should be understood that the above description of mask data preparation 1032 has been simplified for the purposes of clarity. In some embodiments, data preparation 1032 includes additional features such as a logic operation (LOP) to modify the IC design layout diagram 1022 according to manufacturing rules. Additionally, the processes applied to IC design layout diagram 1022 during data preparation 1032 may be executed in a variety of different orders.

After mask data preparation 1032 and during mask fabrication 1044, a mask 1045 or a group of masks 1045 are fabricated based on the modified IC design layout diagram 1022. In some embodiments, mask fabrication 1044 includes performing one or more lithographic exposures based on IC design layout diagram 1022. In some embodiments, an electron-beam (e-beam) or a mechanism of multiple e-beams is used to form a pattern on a mask (photomask or reticle) 1045 based on the modified IC design layout diagram 1022. Mask 1045 can be formed in various technologies. In some embodiments, mask 1045 is formed using binary technology. In some embodiments, a mask pattern includes opaque regions and transparent regions. A radiation beam, such as an ultraviolet (UV) or EUV beam, used to expose the image sensitive material layer (e.g., photoresist) which has been coated on a wafer, is blocked by the opaque region and transmits through the transparent regions. In one example, a binary mask version of mask 1045 includes a transparent substrate (e.g., fused quartz) and an opaque material (e.g., chromium) coated in the opaque regions of the binary mask. In another example, mask 1045 is formed using a phase shift technology. In a phase shift mask (PSM) version of mask 1045, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1044 is used in a variety of processes. For example, such a mask(s) is used in an ion implantation process to form various doped regions in semiconductor wafer 1053, in an etching process to form various etching regions in semiconductor wafer 1053, and/or in other suitable processes.

IC fab 1050 is an IC fabrication business that includes one or more manufacturing facilities for the fabrication of a variety of different IC products. In some embodiments, IC Fab 1050 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1050 includes wafer fabrication tools 1052 configured to execute various manufacturing operations on semiconductor wafer 1053 such that IC device 1060 is fabricated in accordance with the mask(s), e.g., mask 1045. In various embodiments, fabrication tools 1052 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1050 uses mask(s) 1045 fabricated by mask house 1030 to fabricate IC device 1060. Thus, IC fab 1050 at least indirectly uses IC design layout diagram 1022 to fabricate IC device 1060. In some embodiments, semiconductor wafer 1053 is fabricated by IC fab 1050 using mask(s) 1045 to form IC device 1060. In some embodiments, the IC fabrication includes performing one or more lithographic exposures based at least indirectly on IC design layout diagram 1022. Semiconductor wafer 1053 includes a silicon substrate or other proper substrate having material layers formed thereon. Semiconductor wafer 1053 further includes one or more of various doped regions, dielectric features, multilevel interconnects, and the like (formed at subsequent manufacturing steps).

In some embodiments, an IC device includes a first transistor positioned on a front side of a semiconductor substrate, the first transistor including a first gate electrode, first and second epitaxial regions, a first channel extending between the first and second epitaxial regions and through the first gate electrode, and first and second MD segments directly overlying the respective first and second epitaxial regions, a first power rail positioned on a back side of the semiconductor substrate, a first via structure extending from the first epitaxial region to the first power rail, and a second via structure extending from the first MD segment to the first power rail. In some embodiments, the first via structure is aligned with an edge of the first power rail. In some embodiments, the second via structure is aligned with an edge of the first MD segment. In some embodiments, the IC device includes a second transistor positioned on the front side of the semiconductor substrate, the second transistor including a second gate electrode, the second epitaxial region and a third epitaxial region, a second channel extending between the second and third epitaxial regions and through the second gate electrode, and the second MD segment and a third MD segment directly overlying the third epitaxial region, and a third via structure extending from the third epitaxial region to the first power rail, wherein the second via structure extends from the third MD segment to the first power rail. In some embodiments, the IC device includes a second transistor positioned on the front side of the semiconductor substrate, the second transistor including a second gate electrode aligned with the first gate electrode in a first direction, third and fourth epitaxial regions, a second channel extending between the third and fourth epitaxial regions and through the second gate electrode, and third and fourth MD segments directly overlying the respective third and fourth epitaxial regions and aligned with the respective first and second MD segments in the first direction, a second power rail positioned on the back side of the semiconductor substrate, a third via structure extending from the third epitaxial region to the second power rail, and a fourth via structure extending from the third MD segment to the second power rail. In some embodiments, the first and second transistors are different types of an n-type transistor or p-type transistor. In some embodiments, the first through fourth epitaxial regions have a same width in the first direction. In some embodiments, each of the first and second transistors is a first type of an n-type transistor or p-type transistor, and the IC device includes a third transistor positioned between the first and second transistors, wherein the third transistor is a second type of the n-type transistor or p-type transistor. In some embodiments, the third transistor includes fifth and sixth epitaxial regions having a width in the first direction approximately twice a width of the first through fourth epitaxial regions in the first direction.

In some embodiments, an IC device includes a first plurality of gate structures extending in a first direction on a front side of a semiconductor wafer, a plurality of first epitaxial regions positioned between corresponding gate structures of the first plurality of gate structures and aligned with each other in a second direction perpendicular to the first direction, a plurality of first MD segments extending in the first direction and directly overlying corresponding first epitaxial regions of the plurality of first epitaxial regions, a first power rail extending in the second direction on a back side of the semiconductor wafer, a plurality of first via structures extending from the first power rail to corresponding first epitaxial regions of the plurality of first epitaxial regions, and a plurality of second via structures extending from the first power rail to corresponding first MD segments of the plurality of first MD segments. In some embodiments, the IC device includes a plurality of second epitaxial regions positioned between corresponding gate structures of the first plurality of gate structures and aligned with each other in the second direction, a plurality of second MD segments extending in the first direction and directly overlying corresponding second epitaxial regions of the plurality of second epitaxial regions, a second power rail extending in the second direction on the back side of the semiconductor wafer, a plurality of third via structures extending from the second power rail to corresponding second epitaxial regions of the plurality of second epitaxial regions, and a plurality of fourth via structures extending from the second power rail to corresponding second MD segments of the plurality of second MD segments. In some embodiments, the IC device includes a plurality of third epitaxial regions positioned between corresponding gate structures of the first plurality of gate structures, positioned between the pluralities of first and second epitaxial regions in the first direction, and aligned with each other in the second direction, wherein the first and second epitaxial regions of the pluralities of first and second epitaxial regions have a first doping type and a first width in the first direction, and the third epitaxial regions of the plurality of third epitaxial regions have a second doping type different from the first doping type and a second width in the first direction greater than the first width. In some embodiments, the IC device includes a second plurality of gate structures extending in the first direction on the front side of the semiconductor wafer, and pluralities of fourth and fifth epitaxial regions positioned between corresponding gate structures of the second plurality of gate structures and aligned with each other in the second direction, wherein the fourth and fifth epitaxial regions of the pluralities of fourth and fifth epitaxial regions have the first width in the first direction, and the pluralities of fourth and fifth epitaxial regions are offset from the pluralities of first through third epitaxial regions in one of the first or second directions. In some embodiments, the first epitaxial regions of the plurality of first epitaxial regions have a first doping type, and the second epitaxial regions of the plurality of second epitaxial regions have a second doping type different from the first doping type. In some embodiments, the IC device includes a second plurality of gate structures extending in the first direction on the front side of the semiconductor wafer, and pluralities of third and fourth epitaxial regions positioned between corresponding gate structures of the second plurality of gate structures and aligned with each other in the second direction, wherein the first and second epitaxial regions of the pluralities of first and second epitaxial regions have a first width in the first direction, the third and fourth epitaxial regions of the pluralities of third and fourth epitaxial regions have a second width in the first direction less than the first width, and the pluralities of third and fourth epitaxial regions are offset from the pluralities of first and second epitaxial regions in one of the first or second directions.

In some embodiments, a method of manufacturing an IC device includes forming first and second epitaxial regions on a front side of a semiconductor wafer, constructing a first gate electrode and a first channel extending between the first and second epitaxial regions and through the first gate electrode, forming first and second MD segments directly overlying the respective first and second epitaxial regions, forming a first via structure extending from the first epitaxial region to a back side of the semiconductor substrate, forming a second via structure extending from the first MD segment to the back side of the semiconductor substrate, and constructing a first power rail overlying each of the first and second via structures on the back side of the semiconductor substrate. In some embodiments, forming the first and second epitaxial regions includes forming a third epitaxial region on the front side of the semiconductor wafer, constructing the first gate electrode and the first channel includes constructing a second gate electrode and a second channel extending between the second and third epitaxial regions and through the second gate electrode, forming the first and second MD segments includes forming a third MD segment directly overlying the third epitaxial region, forming the first via structure includes forming a third via structure extending from the third epitaxial region to the back side of the semiconductor substrate, forming the second via structure includes forming the second via structure further extending from the third MD segment to the back side of the semiconductor substrate, and constructing the first power rail includes constructing the first power rail further overlying the third via structure on the back side of the semiconductor substrate. In some embodiments, forming the first and second epitaxial regions includes forming third and fourth epitaxial regions on the front side of the semiconductor wafer, constructing the first gate electrode and the first channel includes constructing a second gate electrode and a second channel extending between the third and fourth epitaxial regions and through the second gate electrode, forming the first and second MD segments includes forming third and fourth MD segments directly overlying the respective third and fourth epitaxial regions, forming the first via structure includes forming a third via structure extending from the third epitaxial region to the back side of the semiconductor substrate, forming the second via structure includes forming a fourth via structure extending from the fourth MD segment to the back side of the semiconductor substrate, and constructing the first power rail includes constructing a second power rail overlying each of the third and fourth via structures on the back side of the semiconductor substrate. In some embodiments, forming the first and second epitaxial regions includes forming fifth and sixth epitaxial regions between the third and fourth epitaxial regions, the fifth and sixth epitaxial regions have a width greater than a width of the first through fourth epitaxial regions, and the fifth and sixth epitaxial regions have a doping type different from a doping type of the first through fourth epitaxial regions. In some embodiments, forming the first and second epitaxial regions includes forming the first and second epitaxial regions having a doping type different from a doping type of the third and fourth epitaxial regions.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

What is claimed is:

1. An integrated circuit (IC) device comprising:
a first transistor positioned on a front side of a semiconductor substrate, the first transistor comprising:
a first gate electrode;
first and second epitaxial regions;
a first channel extending between the first and second epitaxial regions and through the first gate electrode; and
first and second metal-like defined (MD) segments directly overlying the respective first and second epitaxial regions;
a first power rail positioned on a back side of the semiconductor substrate;
a first via structure extending from the first epitaxial region to the first power rail; and
a second via structure extending from the first MD segment to the first power rail.

2. The IC device of claim 1, wherein the first via structure is aligned with an edge of the first power rail.

3. The IC device of claim 1, wherein the second via structure is aligned with an edge of the first MD segment.

4. The IC device of claim 1, further comprising:
a second transistor positioned on the front side of the semiconductor substrate, the second transistor comprising:
a second gate electrode;
the second epitaxial region and a third epitaxial region;
a second channel extending between the second and third epitaxial regions and through the second gate electrode; and
the second MD segment and a third MD segment directly overlying the third epitaxial region; and
a third via structure extending from the third epitaxial region to the first power rail,
wherein the second via structure extends from the third MD segment to the first power rail.

5. The IC device of claim 1, further comprising:
a second transistor positioned on the front side of the semiconductor substrate, the second transistor comprising:
a second gate electrode aligned with the first gate electrode in a first direction;
third and fourth epitaxial regions;
a second channel extending between the third and fourth epitaxial regions and through the second gate electrode; and
third and fourth MD segments directly overlying the respective third and fourth epitaxial regions and aligned with the respective first and second MD segments in the first direction;
a second power rail positioned on the back side of the semiconductor substrate;
a third via structure extending from the third epitaxial region to the second power rail; and
a fourth via structure extending from the third MD segment to the second power rail.

6. The IC device of claim 5, wherein
the first and second transistors are different types of an n-type transistor or p-type transistor.

7. The IC device of claim 6, wherein
the first through fourth epitaxial regions have a same width in the first direction.

8. The IC device of claim 5, wherein
each of the first and second transistors is a first type of an n-type transistor or p-type transistor, and
the IC device further comprises a third transistor positioned between the first and second transistors, wherein the third transistor is a second type of the n-type transistor or p-type transistor.

9. The IC device of claim 8, wherein
the third transistor comprises fifth and sixth epitaxial regions having a width in the first direction approximately twice a width of the first through fourth epitaxial regions in the first direction.

10. An integrated circuit (IC) device comprising:
a first plurality of gate structures extending in a first direction on a front side of a semiconductor wafer;
a plurality of first epitaxial regions positioned between corresponding gate structures of the first plurality of gate structures and aligned with each other in a second direction perpendicular to the first direction;
a plurality of first metal-like defined (MD) segments extending in the first direction and directly overlying corresponding first epitaxial regions of the plurality of first epitaxial regions;
a first power rail extending in the second direction on a back side of the semiconductor wafer;
a plurality of first via structures extending from the first power rail to corresponding first epitaxial regions of the plurality of first epitaxial regions; and
a plurality of second via structures extending from the first power rail to corresponding first MD segments of the plurality of first MD segments.

11. The IC device of claim 10, further comprising:
a plurality of second epitaxial regions positioned between corresponding gate structures of the first plurality of gate structures and aligned with each other in the second direction;
a plurality of second MD segments extending in the first direction and directly overlying corresponding second epitaxial regions of the plurality of second epitaxial regions;
a second power rail extending in the second direction on the back side of the semiconductor wafer;
a plurality of third via structures extending from the second power rail to corresponding second epitaxial regions of the plurality of second epitaxial regions; and
a plurality of fourth via structures extending from the second power rail to corresponding second MD segments of the plurality of second MD segments.

12. The IC device of claim 11, further comprising:
a plurality of third epitaxial regions positioned between corresponding gate structures of the first plurality of gate structures, positioned between the pluralities of first and second epitaxial regions in the first direction, and aligned with each other in the second direction, wherein
the first and second epitaxial regions of the pluralities of first and second epitaxial regions have a first doping type and a first width in the first direction, and
the third epitaxial regions of the plurality of third epitaxial regions have a second doping type different from the first doping type and a second width in the first direction greater than the first width.

13. The IC device of claim 12, further comprising:
a second plurality of gate structures extending in the first direction on the front side of the semiconductor wafer; and
pluralities of fourth and fifth epitaxial regions positioned between corresponding gate structures of the second plurality of gate structures and aligned with each other in the second direction, wherein
the fourth and fifth epitaxial regions of the pluralities of fourth and fifth epitaxial regions have the first width in the first direction, and
the pluralities of fourth and fifth epitaxial regions are offset from the pluralities of first through third epitaxial regions in one of the first or second directions.

14. The IC device of claim 11, wherein
the first epitaxial regions of the plurality of first epitaxial regions have a first doping type, and
the second epitaxial regions of the plurality of second epitaxial regions have a second doping type different from the first doping type.

15. The IC device of claim 14, further comprising:
a second plurality of gate structures extending in the first direction on the front side of the semiconductor wafer; and
pluralities of third and fourth epitaxial regions positioned between corresponding gate structures of the second plurality of gate structures and aligned with each other in the second direction, wherein
the first and second epitaxial regions of the pluralities of first and second epitaxial regions have a first width in the first direction,
the third and fourth epitaxial regions of the pluralities of third and fourth epitaxial regions have a second width in the first direction less than the first width, and
the pluralities of third and fourth epitaxial regions are offset from the pluralities of first and second epitaxial regions in one of the first or second directions.

16. A method of manufacturing an integrated circuit (IC) device, the method comprising:
forming first and second epitaxial regions on a front side of a semiconductor wafer;
constructing a first gate electrode and a first channel extending between the first and second epitaxial regions and through the first gate electrode;
forming first and second metal-like defined (MD) segments directly overlying the respective first and second epitaxial regions;
forming a first via structure extending from the first epitaxial region to a back side of the semiconductor substrate;
forming a second via structure extending from the first MD segment to the back side of the semiconductor substrate; and
constructing a first power rail overlying each of the first and second via structures on the back side of the semiconductor substrate.

17. The method of claim 16, wherein
the forming the first and second epitaxial regions comprises forming a third epitaxial region on the front side of the semiconductor wafer,
the constructing the first gate electrode and the first channel comprises constructing a second gate electrode and a second channel extending between the second and third epitaxial regions and through the second gate electrode,
the forming the first and second MD segments comprises forming a third MD segment directly overlying the third epitaxial region,
the forming the first via structure comprises forming a third via structure extending from the third epitaxial region to the back side of the semiconductor substrate,
the forming the second via structure comprises forming the second via structure further extending from the third MD segment to the back side of the semiconductor substrate, and
the constructing the first power rail comprises constructing the first power rail further overlying the third via structure on the back side of the semiconductor substrate.

18. The method of claim 16, wherein
the forming the first and second epitaxial regions comprises forming third and fourth epitaxial regions on the front side of the semiconductor wafer,
the constructing the first gate electrode and the first channel comprises constructing a second gate electrode and a second channel extending between the third and fourth epitaxial regions and through the second gate electrode,
the forming the first and second MD segments comprises forming third and fourth MD segments directly overlying the respective third and fourth epitaxial regions,
the forming the first via structure comprises forming a third via structure extending from the third epitaxial region to the back side of the semiconductor substrate,
the forming the second via structure comprises forming a fourth via structure extending from the fourth MD segment to the back side of the semiconductor substrate, and
the constructing the first power rail comprises constructing a second power rail overlying each of the third and fourth via structures on the back side of the semiconductor substrate.

19. The method of claim 18, wherein
the forming the first and second epitaxial regions further comprises forming fifth and sixth epitaxial regions between the third and fourth epitaxial regions,
the fifth and sixth epitaxial regions have a width greater than a width of the first through fourth epitaxial regions, and
the fifth and sixth epitaxial regions have a doping type different from a doping type of the first through fourth epitaxial regions.

20. The method of claim 18, wherein
the forming the first and second epitaxial regions further comprises forming the first and second epitaxial regions having a doping type different from a doping type of the third and fourth epitaxial regions.
